(19) United States
(12) Patent Application Publication
(10) Pub. No.: US 2002/0175729 A1
(43) Pub. Date: Nov. 28, 2002

(54) Differential CMOS controlled delay unit

(75) Inventor: Sasan Cyrusian, Scotts Valley, CA (US)

Correspondence Address: BRINKS HOFER GILSON & LIONE, P.O. BOX 10395, CHICAGO, IL, 60611, US

(73) Assignee: Infineon Technologies North America Corp.

(21) Appl. No.: 09/866,269

(22) Filed: May 25, 2001

(51) Int. Cl. H03H 11/26

(52) U.S. Cl. 327/274

(57) ABSTRACT

A high performance differential delay circuit for is revealed. The delay unit may be used in a variety of circuits requiring delay units, including voltage-controlled oscillators, voltage controlled delay lines, delay locked loops, phase accumulators, phase locked loops, and direct frequency syntheses. The circuit is desirably manufactured at one time with CMOS technology, and is therefore relatively immune to temperature changes, manufacturing process variations, input voltage fluctuations, and frequency ranges. The circuit achieves its goals by using a minimum number of transistors, and takes advantage of CMOS manufacturing techniques by balancing the NMOS and PMOS transistors used.

### BACKGROUND OF THE INVENTION

The present invention relates generally to delay units, and the present invention relates more particularly to complementary metal oxide semiconductor (CMOS) delay units used in voltage-controlled oscillators. Many CMOS applications require delay units in order to control a function, to synchronize operations, or bring stability to a circuit. Differential delay circuits are generally preferred over single-input units, but differential delay units tend to have worse noise performance.

One CMOS application requiring a delay unit is a voltage controlled oscillator. A ring oscillator with two delay units allows four output signals spaced at ninety electrical degrees, useful for timing and control purposes. There are only a few known CMOS differential delay circuits that may be used in ring oscillators having only two delay stages. Using CMOS circuitry has several inherent advantages, including low cost, small size, good insulation from the substrate and protection from power noise. It is difficult to design for ring oscillators with only two delay stages, since the delay stages need to have a gain higher than one and a phase shift of 90 degrees at the same time. However, differential ring oscillators with only two delay stages are desirable, since they offer better phase noise and jitter performance, as compared to a ring oscillator having more than two delay stages and the same power consumption level.

FIG. 1 depicts a prior art delay cell 10. The prior art delay cell 10 includes linear gain amplifier transistors 11, load transistors 12 and 13, a current source transistor 14, and a bias input voltages 16 and 18. The negative MOS (NMOS) input transistors 11 constitute a linear gain amplifier. The positive MOS (PMOS) devices 12 and 13 are loads. Note that transistors 12 are connected into the circuit as diodes, that is, with their gates shorted to their drains. The delay of the delay cell 10 is changed through control of the tail current source 14 and transistor 17. Increasing the tail current by increasing bias voltage 16 increases the transconductance gm of the input transistors 11. This has the effect of increasing the gain or speed of the cell. For proper functioning of the delay cell, a corresponding increase is needed in the gₘ of PMOS load transistors 12 and 13.

In another way of using this device, reducing the second bias voltage 18, also increases the gₘ of the PMOS devices connected to this node. Second bias voltage 18 is set in such a way that the gₘ of the devices connected to the second bias voltage 18 is the same the gₘ of diode connected PMOS devices 12 when the input differential voltage is zero. In an ideal case, the gain of the delay cell 10 remains the same for higher or lower tail current, but the gₘ of the differential input stage and load elements are increased. This increases the speed of the cell. Diode connected PMOS devices are necessary in order to define the output common mode voltage level. This device is thus both complicated and also limited in its functions.

FIG. 2 depicts a prior art delay unit 20 using many transistors and connections. Delay unit 20 includes a differential amplifier 21 and a positive feedback amplifier 22, each delay cell made of four transistors. The differential amplifier 21 includes transistors 23 and 26, while the positive feedback amplifier 22 includes transistors 24 and 25. Transistors 23 and 24 are NMOS transistors while transistors 25, 26 are PMOS transistors. The vertical series of transistors, pairing an NMOS upper transistor 23, 24 with a lower PMOS transistor 25, 26, constitute complementary amplifiers, with their gates connected as input terminals and their drains connected as an output terminal.

With their sources connected, the several transistors 23, 26 act as a differential amplifier, receiving an input signal from input terminals V_{in 1} and V_{in 2}. The differential amplifier amplifies the input signals and sends output voltages Vₒᵤₜ₂, charging and discharging capacitors Cs₁ and Cs₂. Transistors 24, 25 constitute a positive feedback circuit, in that their gates are tied to their drains, and to the output of the differential amplifier. The diagram also depicts inherent parasitic capacitance of the circuit. When input signals are placed into the input terminals, the differential amplifier charges and discharges the capacitances to form differential outputs The delay of the delay cell is set by the capacitances and the discharge currents. Controlling transistor 28 determines the discharge current, and hence transistor 28 must be able to supply more current than is available through transistors 23 and 24.

The circuit of FIG. 2 thus is limited by the requirement of a large number of transistors, nine, and the inherent parasitic capacitance associated with the size of the circuit. Some of the problems of present circuits include long trains of transistors required for a single delay unit. These longer trains tend to suffer even more from some of the noise disadvantages of such circuits, especially low-frequency noise. Other circuits cannot be used in applications where the environment may include wide temperature or process variations. Such circuits may also suffer from non-symmetry between rise times and fall times of the circuit. A better controlled delay unit is needed.

### BRIEF SUMMARY

In order to address the deficiencies of the prior art, a better delay unit is disclosed that meets these needs by minimizing the number of transistors and components in a delay unit. Also disclosed is a voltage controlled oscillator or frequency synthesizer that employs at least two of these delay units.

One embodiment includes a differential controlled delay unit having a positive feedback amplifier and a linear amplifier, each amplifier having two transistors. The positive feedback amplifier has two transistors connected back-to-back, in which the gate of one transistor is connected to the source of the other transistor. A control input voltage, acting also as a positive power supply, is connected to the drains to the transistors. The outputs or sources of the positive feedback amplifier are connected to inputs or drains of a linear amplifier, the linear amplifier also having two transistors. A differential voltage is input to the gates of the linear amplifier. The output of the delay unit is taken from the joined outputs of the positive feedback amplifier and the linear amplifier.

Another embodiment includes a voltage controlled oscillator using two such delay units in series. The oscillator has a first delay unit and a second delay unit, each having four transistors. In both units, a first and a second transistor are connected as a first amplifier, a two-transistor positive amplifier, with the gate of the first transistor connected to the source of the second transistor, and the source of the second transistor connected to the gate of the first transistor. There is a second amplifier having a third and a fourth transistor, the drains of the third and fourth transistors connector to the sources of the first and third transistors respectively, the connections forming outputs of each of the two delay units. The outputs of the first delay unit are connected to gates of the second amplifier of the second delay unit, and the outputs of the second delay unit are connected to gates of the second amplifier of the first delay unit. A control input and power supply voltage are then connected to the drains of the first amplifiers.

### BRIEF DESCRIPTION OF SEVERAL VIEWS OF THE DRAWINGS

FIGS. 1 and 2 are prior art delay units.

FIGS. 3a and 3b are embodiments of a delay unit.

FIGS. 4a and 4b are further embodiments of a delay unit

FIGS. 5-8 are delay unit embodiments useful for a two-stage voltage controlled oscillator or voltage controlled delay line.

FIG. 9 is an embodiment with an improved voltage-to-frequency circuit using the delay unit.

FIG. 10 is an embodiment of a delay unit embodiment useful as a frequency synthesizer

FIG. 11 is an embodiment with a phase locked loop.

FIG. 12 is an embodiment with a delay locked loop.

FIG. 13 is an embodiment with a phase accumulator.

FIG. 14 is an embodiment of a 6-cell delay line.

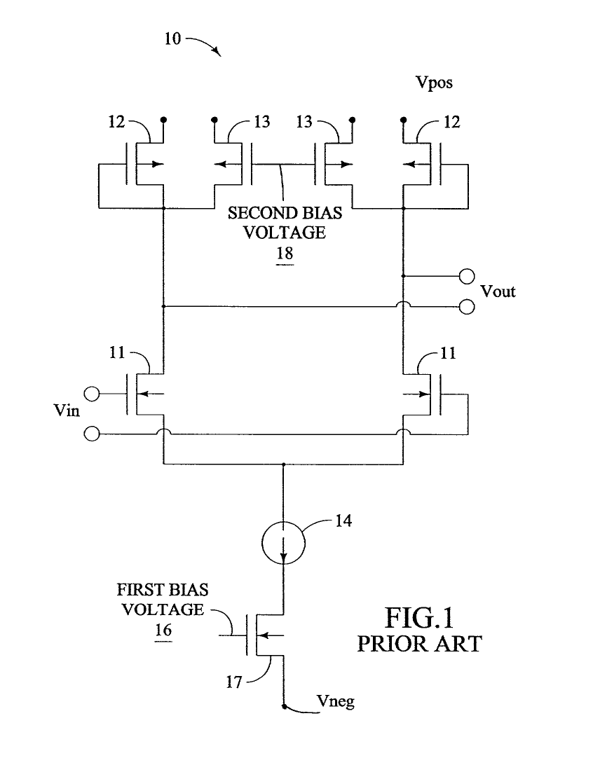

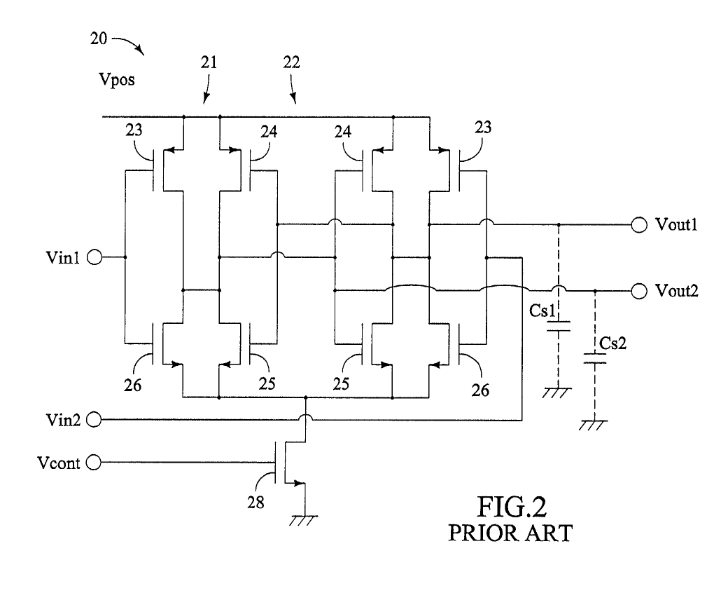

### DETAILED DESCRIPTION OF THE PRESENTLY PREFERRED EMBODIMENTS

In the discussion below, transistors are described as CMOS transistors, and in particular as p-channel MOS (PMOS) or n-channel MOS (NMOS) transistors. Those skilled in the art will recognize that the terms p-channel and n-channel might more accurately describe the transistors discussed herein, since these transistors are typically not manufactured by depositing metallic elements, except possibly for external connections. Rather, source and gate regions are doped to either p-type or n-type, indicating whether the channel between source and drain conducts via depletion mode (holes) or enhancement mode (electrons). Nevertheless, the terms PMOS and NMOS are more-commonly used, and are so used herein to mean those transistors manufactured by CMOS processes.

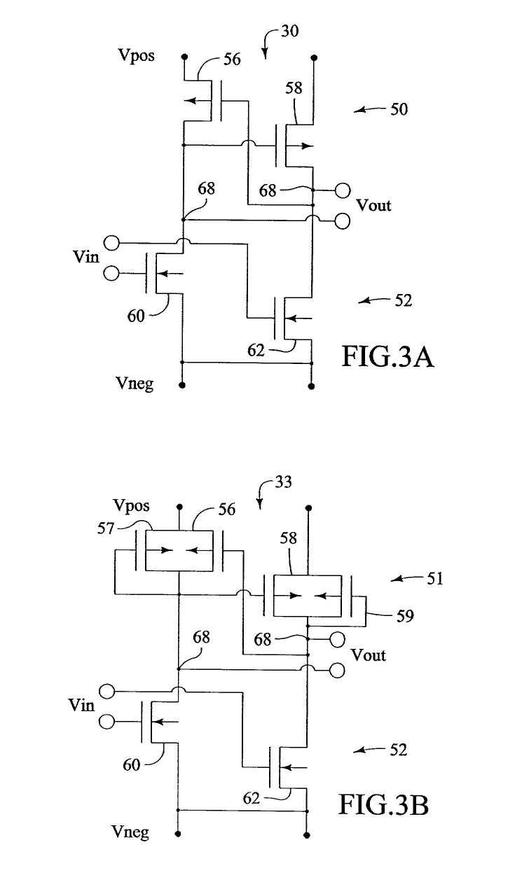

FIG. 3a depicts a delay unit 30 having a positive feedback amplifier 50, a linear amplifier 52, and a differential output voltage. Transistors 56 and 58 are PMOS transistors and are connected back-to-back in the sense that the gate of each transistor is tied to the drain of the other transistor. A supply voltage and control voltage Vₚₒₛ, along with its return or a negative supply, V_{neg}, control the amplifier. The drains of the transistors 56, 58 are connected to a linear amplifier 52, and particularly to the drains of NMOS transistors 60 and 62. A differential voltage signal is connected to the gates of the linear amplifier transistors 60, 62. The voltage output, now having a delay determined by the supply and control voltage and Vᵢₙ, is taken from the Vₒᵤₜ terminals, the joint outputs 68 of the positive feedback amplifier 50 and the input signal to the linear amplifier 52.

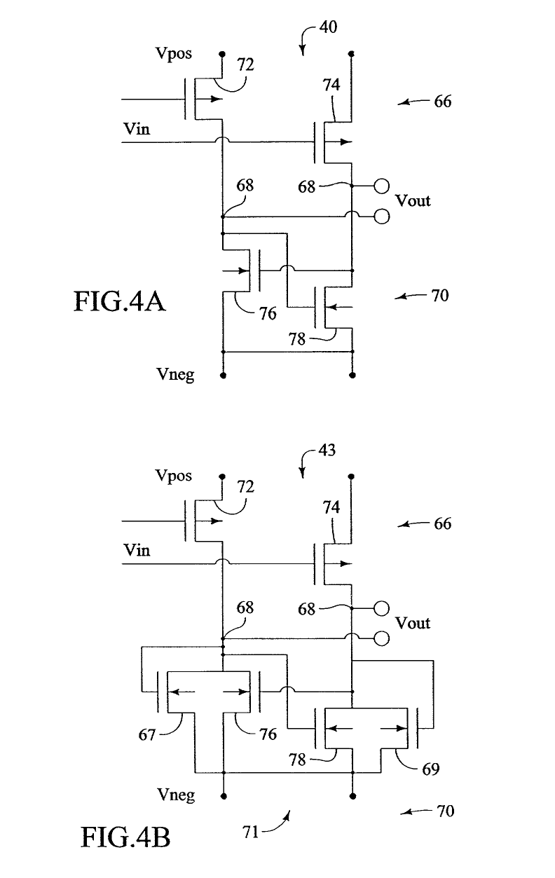

In this configuration, the positive feedback amplifier 50 is wired so that the transistors 56, 58 act as pull-up transistors, while the linear amplifier 52 act as pull-down transistors. Thus, the delay unit is fully differential, with the positive feedback portion 50 coupling the outputs of the linear (differential delay) amplifier 52. The circuit works by forcing both outputs of the delay stage to have 180 degrees phase difference. With this design, and that of FIG. 4a, below, the delay unit is able to use nearly all of the available positive input voltage, that is, there is a large voltage swing, from V_{neg} nearly to the Vₚₒₛ input and control voltage. This allows the delay unit to have a larger range of delay outputs for the user and improves the ratio of oscillation signal to noise. This design also provides for nearly symmetric rise and fall times of the phase outputs of the delay units, whether a single unit or several in series to form a voltage oscillator or frequency synthesizer.

FIG. 3b depicts another way to increase the load of the positive feedback portion 51 of the amplifier 33, by adding “MOS diodes,” that is, additional PMOS transistors 57, 59. Transistors 57, 59 have their gates connected with their drains, in parallel with positive feedback transistors 56, 58. Thus, the “MOS diodes” increase the transconductance of the feedback amplifier 51 portion of the amplifier 33, and thus the ratio of transconductance of the feedback amplifier to the transconductance of the linear amplifier 52 portion, consisting of NMOS transistors 60, 62. The output terminals 68 remain. In one embodiment, the NMOS transistors 60, 62 have an n-channel width of about 5.76 micrometers and a length of about 0.18 micrometers. The PMOS transistors 56, 58 have a p-channel width of about 7.6 micrometers and a length of about 0.18 micrometers. The PMOS diodes 57, 59 have a p-channel width of about 1.0 micrometers and a p-channel length of about 0.18 micrometers.

FIG. 4a depicts a complementary version of the delay unit 40, in which the PMOS and NMOS transistors are essentially reversed as compared to the delay unit 30 of FIG. 3a. This circuit functions similarly. Depending on the properties of the manufacturing process used, such as CMOS manufacturing processes for some embodiments, it may make sense to prefer one implementation to the other. The delay cell 40 includes a linear amplifier 66 and a positive feedback amplifier 70. The delay cell connects to a power source, Vpos and its return or ground, Vneg. The linear amplifier 66 includes PMOS transistors 72, 74. The drains of the PMOS transistors 72, 74 lead to the drains of the NMOS transistors 76, 78 of the positive feedback amplifier 70. The NMOS transistors 76, 78 are connected back-to-back, with the gate of one tied to the drain of the other. The output signal of the delay unit is taken as a differential voltage output at the points of connection 68 between the linear amplifier 66 and the positive feedback amplifier 70. The circuit works by forcing the output signals of the delay stage to have 180 degrees phase difference.

FIG. 4b is another embodiment of a delay unit 43, paralleling “MOS diodes” 67, 69 across positive feedback amplifier portion 71 and positive feedback amplifier NMOS transistors 76, 78. Transistors 67, 69 are NMOS transistors having their gates connected with their drains. The remainder of the delay unit 43 includes linear amplifier 66 and PMOS transistors 72, 74. As is well known, the ratios between the rise and fall times of the delay units may be adjusted by changing the ratio of transconductance or conductivity of NMOS and PMOS transistors of the delay units. In operation, this may be accomplished by adjusting the control voltage and the input (gate) voltage of the delay units. In manufacturing, the channel width and channel length (W/L) of the PMOS and NMOS transistors may also be changed so that the W/L are as desired.

IN CMOS manufacturing, both PMOS and NMOS transistors are manufactured side-by-side. CMOS components are among the smallest commercially available, thus making the transistors and circuits built from them as small as possible. The inherent, parasitic capacitance is thus also kept as small as possible. This provides excellent frequency response and keeps jitter to a minimum. Because all the circuits are manufactured on the same wafer of silicon, the integrated circuits, whether oscillators, delay units, or other circuitry, tend to be affected relatively equally by temperature, environmental conditions, and variations inherent in the manufacturing process. These variations may include humidity, atmospheres, furnace conditions, material lots, or even furnace carriers used. All circuits made at one time tend to be equally affected.

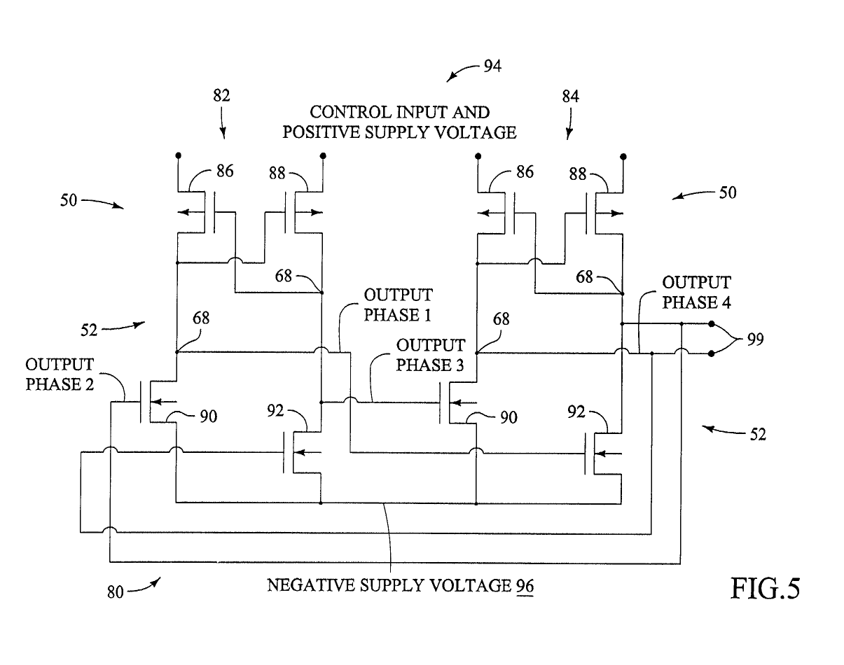

FIG. 5 depicts another embodiment, in which two identical delay units 82 and 84 are connected in series as shown, to form a voltage controlled oscillator 80 (VCO) or voltage-to-frequency converter. In FIG. 5, delay unit 82 depicts a first stage of the VCO 80, while delay unit 84 depicts the second stage, wherein the only difference between the two stages is the manner of connecting their outputs. First delay unit 82 and second delay unit 84 both include a first (feedback) amplifier 50 and a second (linear) amplifier 52. First amplifiers 50 include PMOS transistors 86, 88, connected as positive feedback amplifiers, with a gate of one transistor tied to a drain of the other. Second amplifiers 52 include NMOS transistors 90, 92, connected as linear amplifiers, and with their drains connected to the drains of the first amplifiers 50 as an output signal. The use of the control input and positive supply voltage 94 both as a power source and as a control input takes advantage of the inherent advantages of CMOS technology, connecting to the sources of transistors 86 and 88 in delay units 82 and 84.

The control input to the positive terminals 94 is as shown, and a negative supply voltage (or ground) at terminal 96. The output phases of the respective feedback amplifiers 50 and linear amplifiers 52 are connected as shown at connections 68, in both the first and the second delay units 82, 84. Thus, the first and second amplifiers are connected, with the output of first stage phase 1 and phase 3 connected to the gates of the second phase linear amplifier. The output signal of the second stage unit is taken as shown, with output phase 2 connected to the gate of the linear amplifier transistor 90 of the first stage, and the output phase 4 connected to the gate of first stage transistor 92. The output signal of the VCO is taken from output terminals 99 as shown, wherein the frequency of the output signals will vary with the control input and positive supply voltage. The VCO functions by charging and discharging the inherent parasitic capacitance from its output nodes to positive or negative power nodes and also between different output nodes. The timing of the charging and discharging is dependent on the voltage inputs to the VCO 80 or voltage-to-frequency converter.

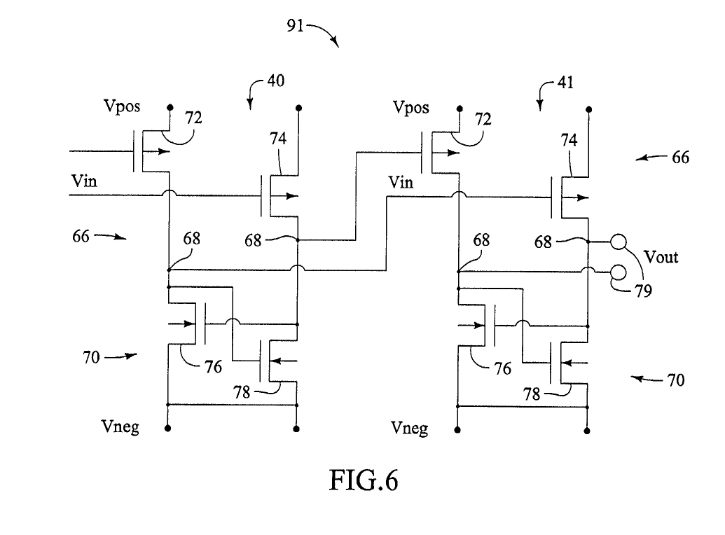

As may be apparent from FIG. 5, and will be shown later in FIG. 6, one or more than one output signal of a VCO may be used, that is one or more than one phase output of a VCO may be used. The embodiments depicted here with the improved delay units deliver all phases, in FIG. 5, four phases, of the same frequency with equal time and phase distance between the outputs, two outputs per delay unit. Thus, in the 2-delay unit VCO of FIG. 5, there are four equidistant phases. A VCO having three differential delay units will yield six equidistant phases, and so on. The output terminals need not be discrete components, but may be any point of contact between traces or conductive paths of the delay unit. Thus, the word “terminal,” whether applied to input terminals, output terminals, or a point of input voltage or current to any drain, source or gate, may mean any point of contact, rather than a specific component meant to be soldered or welded on.

FIG. 6 is another embodiment of a two-delay unit 91 for a VCO, this time using two delay units 40, 41 from FIG. 4a. Delay units 40, 41 each have a first (linear) amplifier 66 and a second (feedback) amplifier 70. The first amplifier 66 of each delay unit has PMOS transistors 72, 74, and the second amplifier 70 of each delay unit has NMOS transistors 76, 78. In the first delay unit 40 of this embodiment, a positive voltage Vₚₒₛ is connected to PMOS transistors 72 and 74, whose drains are connected to drains of NMOS transistors 76, 78. A gate of each NMOS transistor 76, 78 is joined to a drain of the other NMOS transistor, 78, 76. Output connections 68, joining the first and second amplifiers, are connected to the second delay unit 41, and to gates of PMOS transistors 72, 74 of the second delay unit 41. Drains of the PMOS transistors 72, 74 of the second delay unit 41 are joined to the drains of the NMOS transistors 76, 78 of the second delay unit, forming connections 68. Output terminals 79 of the VCO provide an output signal. Note that several delay units in series may constitute a “delay unit” or a “delay line.”

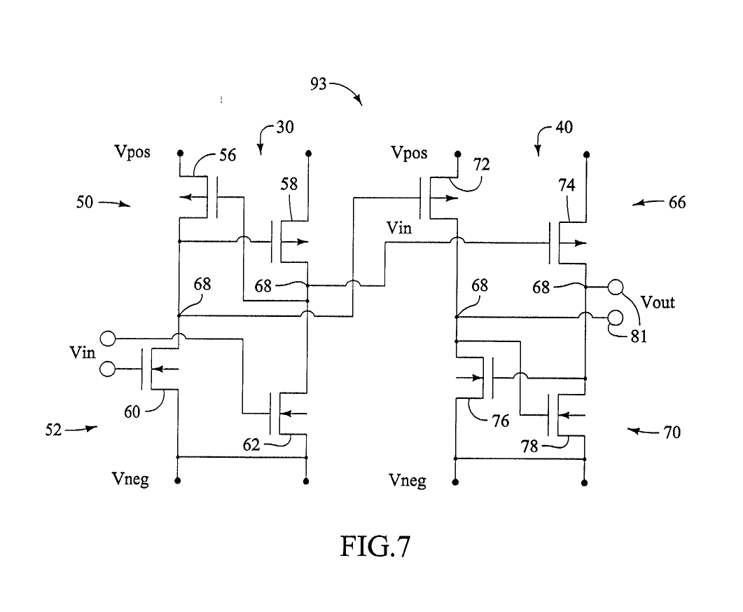

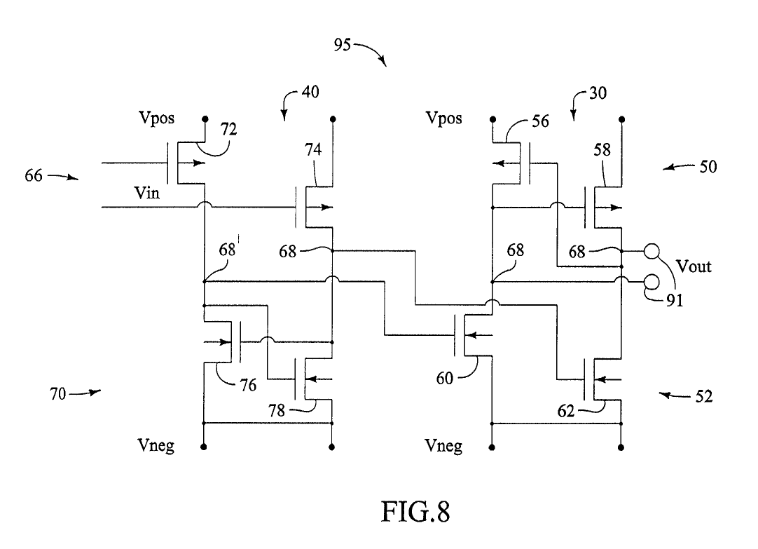

FIGS. 5 and 6 depicted embodiments in which similar versions of two delay units were joined in series to provide a 2-delay unit VCO. Other embodiments may used three or more delay units. In still other embodiments, two or more delay units may be used, including both embodiments of the delay units according to FIGS. 3a, 3b, 4a, and 4b. FIG. 7 depicts a two-delay cell delay unit 93 in which a delay unit 30 according to FIG. 3a is used as a first delay cell, and a delay unit 40 according to FIG. 4a is used as a second delay cell. FIG. 8 depicts an embodiment in which a delay unit 40 is a first delay cell, with a delay unit 30 as the second delay cell. Other embodiments may use more than two delay units, by simply connecting the joined drains of one delay unit to the gates of the next.

In FIG. 7, two delay cell unit 93 has a first delay unit 30 having a first amplifier 50 and a second amplifier 52, joined at connections 68. The first amplifier 50 has PMOS transistors 56, 58, in which a gate of one PMOS transistor is connected to a drain of the other, while the second amplifier 52 has NMOS transistors 60, 62 connected to accept an input voltage. The amplifiers are connected at connections 68 and then to a second delay unit 40. Delay unit 40 is of the complementary type depicted in FIG. 4a, in which first amplifier 66 has PMOS transistors 72, 74, and second amplifier 70 has NMOS transistors 76, 78. Amplifiers 70 and 66 are connected at connections 68, and an output may be taken at terminals 81.

In FIG. 8, the order of the delay units in two-stage delay cell 95 is reversed, with a first delay unit 40 and a second delay unit 30. First delay unit 40 has a first amplifier 66 and second amplifier 70, first amplifier 66 with PMOS transistors 72, 74 connected to receive an input voltage at their gates. The second amplifier 70 has NMOS transistors 76, 78, in which a gate of one transistor is connected to a drain of the other. The first amplifier and the second amplifier are connected at connections 68 by the drains of the several transistors, and thence to the second delay unit 30. Second delay unit 30 has a first amplifier 50 and a second amplifier 52, the two amplifiers connected at connections 68, at which connection an output signal may be taken. First amplifier 50 has back-to-back connections in which a gate of one PMOS transistor 56, 58 is connected to a drain of the other. Second amplifier 52 is connected to receive the input signal from the first delay unit at gates of NMOS transistors 60, 62, and the drains of the transistors are connected to connectors 68.

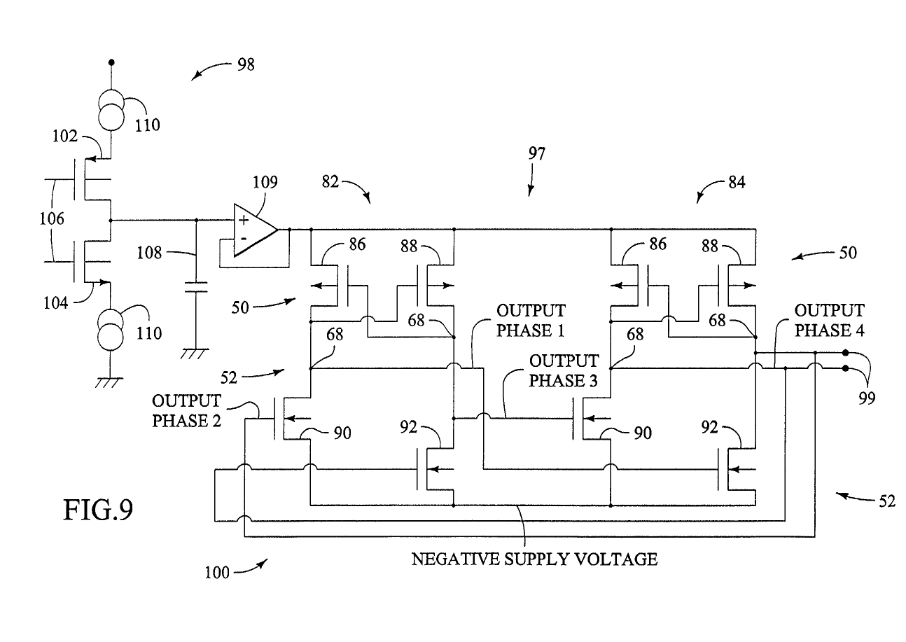

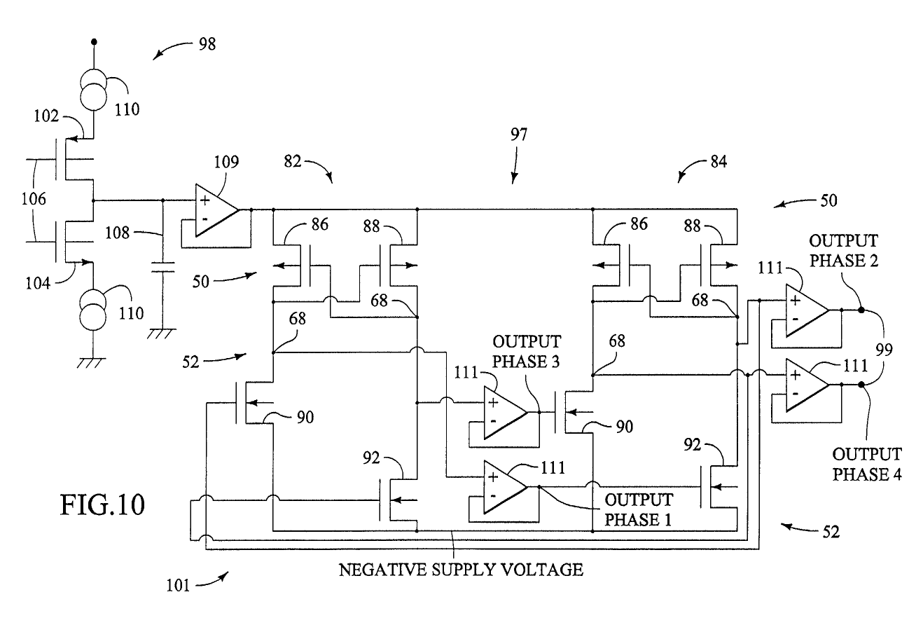

FIG. 9 is another embodiment of a voltage-to-frequency converter 100, this time using an explicit charge pump, 98, a buffer amplifier 109, and a two-unit delay cell 97, similar to that depicted in FIG. 5. Charge pump 98 includes two transistors 102, 104 with gates connected to control inputs 106, and having current sources 110. The output of the charge pump charges and discharges through capacitor 108, and is buffered by buffer amplifier 109. The buffered output voltage then becomes the input voltage to the two-unit delay cell 97, similar to that of FIG. 5, with all elements as previously described. FIG. 10 is another embodiment of a VCO 101, with the output phase signals 1, 2, 3 and 4 connected to amplifiers 111 for the four output phases in two-unit delay cell 97. Each output signal is removed in phase at least 90 degrees from the others.

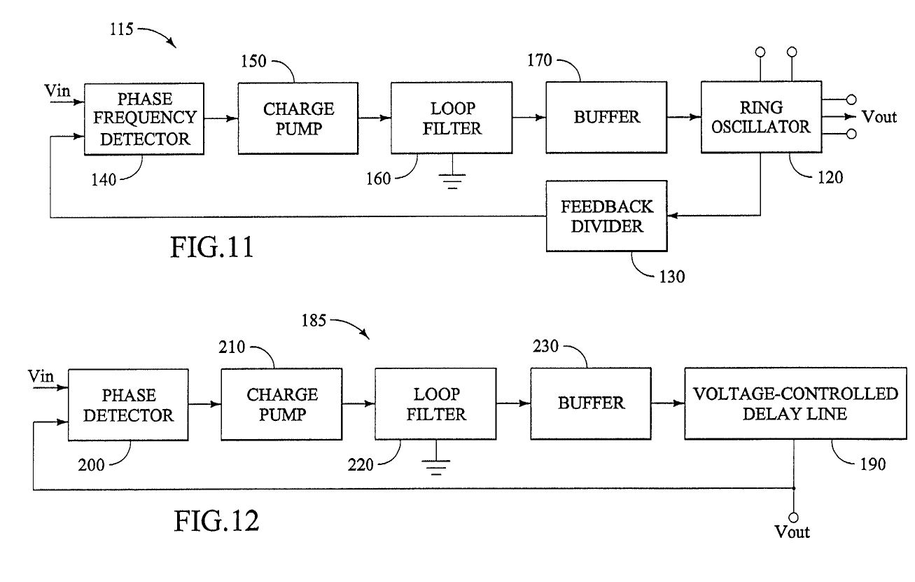

Delay units are also useful in synchronizing outputs or removing a clock delay in a circuit. Two circuits remove clock delay, a phase-locked loop and a delay-locked loop. These circuits may also perform other functions, such as frequency synthesis and phase shifting. FIG. 11 is an embodiment of a phase-locked loop 115 using a delay unit of the above description. A two-delay stage voltage-controlled oscillator (VCO) 120 or voltage-to-frequency converter may send its output signals to voltage divider 130 and simultaneously to a phase frequency detector 140. The VCO will run at input reference frequency, Vin, multiplied by the feedback divider factor from the feedback divider 130. The output of the feedback counter is connected to the feedback input signal of the phase frequency detector 140. The charge pump 150 charges and discharges through a loop filter 160, which includes a resistor in series to a buffer amplifier 170 and a capacitor to ground. Multiple output signals Vₒᵤₜ of each desired phase may be taken from the VCO or ring oscillator 120.

FIG. 12 is an embodiment with a delay locked loop 185. A signal is input into a phase detector 200 simultaneously with a feedback signal from a voltage controlled oscillator 190. If the object of the delay locked loop 185 is to remove a certain amount of delay, the output signal may be exactly one cycle (or an integral number of cycles) removed from the input signal. The output signal of the phase detector 200 then charges a charge pump 210 through loop filter 220. Loop filter 220 may consist only of a capacitor to ground. The output signal is amplified by buffer amplifier 230 and then sent to control the delay line 190.

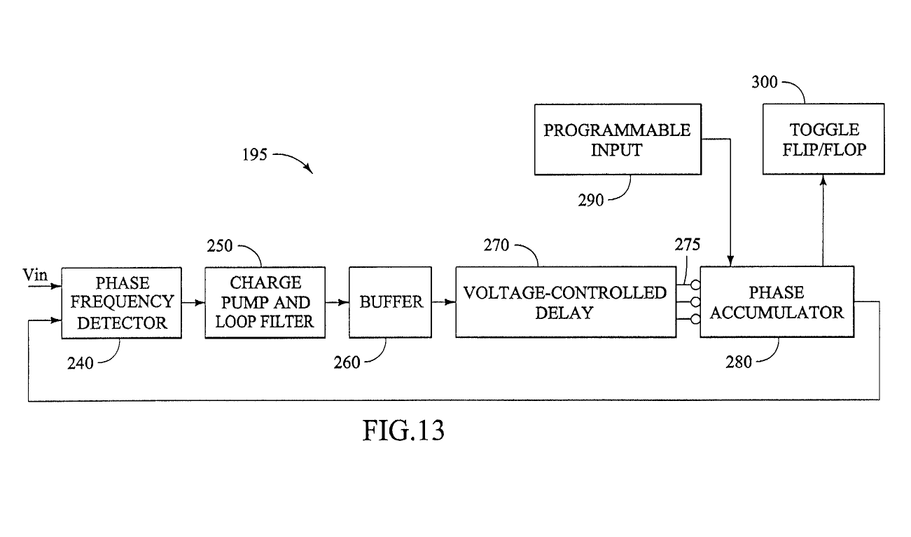

FIG. 13 is an embodiment of a VCO using delay units in a phase accumulator circuit 195. A voltage signal is input to a phase frequency detector 240, along with feedback from a phase accumulator 280. The phase accumulator may have a programmable input 290. The output signal of the phase accumulator may be set to remove a certain amount of delay, and then sent to a charge pump and loop filter 250 and a buffer amplifier 260 before entering the VCO/delay line 270 as a control input and voltage source. All phase output signals 275 from a VCO/delay line 270 may be connected to a phase accumulator 280 and thence used in outside circuits, such as a toggle flip/flop 300. In an 8-delay-unit VCO, there are 16 phase output signals possible. The phase accumulator 280 simply counts, based on the frequency input from the VCO 270. The frequency is added to the value of the current count. The counter will reach its maximum value and then roll over. The higher the frequency, the faster the counter will continue to turn over.

In one embodiment, phase accumulator 280 starts at rising edge of the first output signal 275 of the VCO 270 and stops at the rising edge of nth output. In one embodiment, n may be from 1 to 17 inclusive. The phase accumulator 280 then restarts at first rising edge. It toggles a flip/flop 300 at the first and nth rising edge. Since n is programmable, the toggle frequency can be programmed. In another embodiment, the accumulator generates a toggle signal at a first rising edge. It generates a second toggle signal at nth rising edge. It generates a third toggle signal at (2*(1−n)+1) rising edge. It generates additional toggle signals by increasing 2 (in the above formula) to 3 and so on. If the number of phase outputs is larger than 16, the programmable unit may subtract 16 from it and generate an additional toggle signal at this rising edge and so on. Please note that all toggle signals are essentially the same signal.

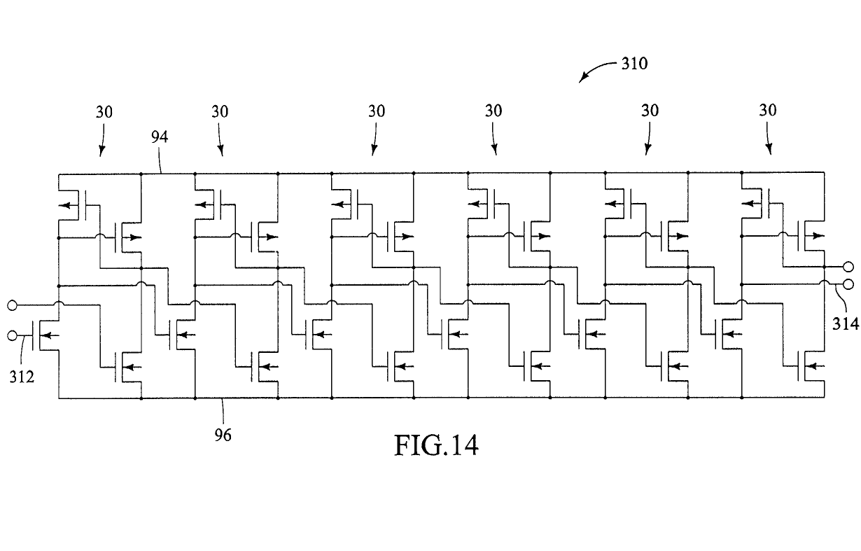

Although only a few embodiments of the invention have been discussed, other embodiments are contemplated For example, delay units may be used in many other kinds of instruments or circuits requiring jitter-free oscillators or frequency generators. The embodiments featured use only one or two delay units in tandem, but embodiments with multiple units may also be used. For instance, a frequency generator or counter may be divided into decades, and one or more delay units provided for each decade. Many other circuits requiring an oscillator, a frequency generator, a phase-locked loop, a delay-lock loop, or a phase accumulator may also benefit from the present invention. FIG. 14 depicts an example of a 6-cell delay line 310, having 6 delay units 30 connected in series, receiving a control and supply voltage at rail 94 and a return or negative supply voltage at rail 96, receiving an input differential voltage signal at terminals 312, and outputting a differential output voltage signal at output terminals 314. Of course, other outputs and phase outputs may be taken from internal connections of the delay units of the delay line 310.

It is therefore intended that the foregoing description illustrates rather than limits this invention, and that it is the following claims, including all equivalents, which define this invention. Of course, it should be understood that a wide range of changes and modifications may be made to the embodiments described above. Accordingly, it is the intention of the applicants to protect all variations and modifications within the valid scope of the present invention.

What is claimed is:

1. A differential controlled delay unit, comprising:
a first amplifier having a first and a second transistor connected as a two-transistor positive amplifier, wherein a gate of the first transistor is connected to a drain of the second transistor and a gate of the second transistor is connected to a drain of the first transistor; and
a second amplifier having a third and a fourth transistor, a drain of the third and fourth transistors connected to a drain of the first and second transistors to form output terminals, wherein a differential input voltage is connected to gates of the second amplifier transistors, and a control input and power supply voltage is connected to drains of the first amplifier.

2. The delay unit of claim 1, wherein the first amplifier transistors are PMOS transistors and the second amplifier transistors are NMOS transistors.

3. The delay unit of claim 1, wherein a positive supply voltage is connected to the first amplifier and a negative supply voltage is connected to the second amplifier.

4. A differential controlled delay unit, comprising:
a first amplifier having a first and a second transistor connected as a two-transistor positive amplifier, wherein a gate of the first transistor is connected to a drain of the second transistor and a gate of the second transistor is connected to a drain of the first transistor; and
a second amplifier having a third and a fourth transistor, wherein a drain of the third and fourth transistors is connected to a drain of the first and second transistors to form output terminals, and a differential input voltage is connected to gates of the third and fourth transistors, and a control input and supply voltage is connected to the sources of the second amplifier.

5. The delay unit of claim 4, wherein the first amplifier transistors are NMOS transistors and the second amplifier transistors are PMOS transistors.

6. The delay unit of claim 4, wherein a positive supply voltage is connected to the second amplifier and a negative supply voltage is connected to the first amplifier.

7. A voltage controlled oscillator, comprising:
a first delay unit and a second delay unit, each further comprised of four transistors, said delay units each having a first amplifier having a first and a second transistor connected as a two-transistor positive amplifier, wherein a gate of the first transistor is connected to a drain of the second transistor and a gate of the second transistor is connected to a drain of the first transistor, said delay units each having a second amplifier having a third and a fourth transistor,
wherein a drain of the third and fourth transistors is connected to a drain of the first and second transistors, said connections forming output terminals of the delay unit, and
wherein output terminals of the first delay unit are connected to gates of the second amplifier of the second delay unit, and output terminals of the second delay unit are connected to gates of the second amplifier of the first delay unit, and wherein a control input and power supply voltage is connected to sources of the first amplifiers.

8. The voltage controlled oscillator of claim 7, wherein the transistors for the first amplifiers are PMOS transistors and the transistors for the second amplifiers are NMOS transistors.

9. The voltage controlled oscillator of claim 7, wherein a positive supply voltage is connected to the first amplifiers and a negative supply voltage or ground is connected to the second amplifiers.

10. The voltage controlled oscillator of claim 7, further comprising an additional delay unit, wherein output signals from the second delay unit are connected to gates of the additional delay unit, and output signals of the additional delay unit are connected to gates of the first delay unit.

11. The voltage controlled oscillator of claim 7, wherein the transistors for the first amplifiers are PMOS and the transistors for the second amplifiers are NMOS and a drain of the first and second transistors is connected to a drain of the third and fourth transistors to form outputs of the delay units,
and wherein outputs of the first delay unit are connected to gates of the second delay unit, and outputs of the second delay unit are connected to gates of the first delay unit, and wherein a control input and power supply voltage is connected to sources of the second amplifiers.

12. The voltage controlled oscillator of claim 11, further comprising an additional delay unit, wherein outputs from the second delay unit are connected to gates of the additional delay unit, and outputs of the additional delay unit are connected to gates of the first delay unit.

13. The voltage controlled oscillator of claim 7, wherein in the first delay unit and the second delay unit, drains of the first amplifier are connected to drains of the second amplifier to form output terminals,
and wherein the output signals of the first delay unit are connected to gates of the second delay unit, and output signals of the second delay unit are connected to gates of the first delay unit, and wherein a control input and power supply voltage is connected to sources of the first and second delay units.

14. The voltage controlled oscillator of claim 13, further comprising an additional delay unit, wherein output signals from the second delay unit are connected to gates of the additional delay unit, and output signals of the additional delay unit are connected to gates of the first delay unit.

15. The voltage controlled oscillator of claim 7, wherein in the first delay unit and in the second delay unit, drains of the first amplifier are connected to sources of the second amplifier, said connections forming output terminals,
and wherein output terminals of the first delay unit are connected to gates of the second delay unit, and output terminals of the second delay unit are connected to gates of the first delay unit.

16. The voltage controlled oscillator of claim 15, further comprising an additional delay unit, wherein output signals from the second delay unit are connected to gates of the additional delay unit, and output signals of the additional delay unit are connected to gates of the first input unit.

17. The voltage controlled oscillator of claim 15, wherein the transistors of the first amplifiers are PMOS and the transistors of the second amplifiers are NMOS.

18. The voltage controlled oscillator of claim 7, further comprising a charge pump and a buffer, wherein a buffered output voltage of the charge pump is a supply voltage to the first amplifiers.

19. The voltage controlled oscillator of claim 7, further comprising at least one additional delay unit, wherein output terminals of a delay unit are connected to gates of a next delay unit, and output terminals of a last delay unit are connected to the gates of the first delay unit.

20. A phase-locked loop, comprising:
a phase frequency detector;
a charge pump and loop filter connected to the phase frequency detector;
a voltage controlled oscillator having at least two delay units, each delay unit further comprising four transistors, and connected with a supply and control voltage from the charge pump; and
a voltage divider connected between the oscillator and the phase frequency detector.

21. The phase-locked loop of claim 20, further comprising a buffer connected between the charge pump and the voltage controlled oscillator.

22. A delay locked loop, comprising:
a phase detector;
a charge pump and loop filter connected with the phase detector;
a buffer amplifier; and
a voltage controlled delay line having at least two delay units, each delay unit further comprising four transistors, and connected with a supply and control voltage from the charge pump and buffer amplifier, the voltage control oscillator also connected with the phase detector.

23. A phase accumulator circuit, comprising:
a phase frequency detector;
a charge pump and loop filter, connected with the phase frequency detector;
a buffer amplifier connected with the charge pump and loop filter;
a voltage controlled oscillator having at least two delay units, each delay unit further comprising four transistors, and connected with a supply and control voltage from the charge pump and buffer amplifier;
a phase accumulator, connected with the voltage controlled oscillator and receiving inputs from the oscillator;
a programmable control input, connected to the phase accumulator; and
at least one toggle flip/flop, connected to the phase accumulator and receiving inputs from the phase accumulator.
